(19) United States
(12) Patent Application Publication
(10) Pub. No.: US 2025/0068083 A1
(43) Pub. Date: Feb. 27, 2025

(54) CATADIOPTRIC PROJECTION OBJECTIVE, PROJECTION ILLUMINATION SYSTEM AND PROJECTION ILLUMINATION METHOD

(71) Applicant: Carl Zeiss SMT GmbH, Oberkochen (DE)

(72) Inventors: Susanne Beder, Aalen (DE); Stig Bieling, Aalen (DE); Markus Schwab, Aalen (DE)

(21) Appl. No.: 18/948,801

(22) Filed: Nov. 15, 2024

Related U.S. Application Data
(63) Continuation of application No. PCT/EP2023/062883, filed on May 15, 2023.

(30) Foreign Application Priority Data
May 25, 2022 (DE) 10 2022 205 272.2

(51) Int. Cl. G03F 7/00; G02B 17/08

(52) U.S. Cl. CPC G03F 7/70225; G02B 17/08; G03F 7/70075; G03F 7/70091; G03F 7/70208

(57) ABSTRACT

A catadioptric projection objective for reproducing a pattern arranged in an object plane of the projection objective in an image plane of the projection objective parallel to the object plane comprises a plurality of optical elements comprises lenses and concave mirrors arranged between the object plane and the image plane along an optical axis. The projection objective is a double-field projection objective to reproduce a first effective object field outside the optical axis in the object plane along a first projection beam path in a first effective image field outside the optical axis in the image plane and at the same time to reproduce a second effective object field, opposite the first object field in relation 10 to the first optical axis, outside the optical axis in the object plane along a second projection beam path in a second effective image field outside the optical axis in the image plane.

### CROSS-REFERENCE TO RELATED APPLICATIONS

The present application is a continuation of, and claims benefit under 35 USC 120 to, international application No. PCT/EP2023/062883, filed May 15, 2023, which claims benefit under 35 USC 119 of German Application No. 10 2022 205 272.2, filed on May 25, 2022. The entire disclosure of each of these applications is incorporated by reference herein.

### FIELD

The disclosure relates to a catadioptric projection lens for imaging a pattern arranged in an object plane of the projection lens into an image plane, parallel to the object plane, of the projection lens. The disclosure furthermore relates to a projection exposure apparatus having such a projection lens and to a projection exposure method which can be carried out with the aid of the projection lens.

### BACKGROUND

These days, microlithographic projection exposure methods are predominantly used for producing semiconductor devices and other finely structured components. Masks (reticles) that carry or create the pattern of a structure to be imaged, e.g. a line pattern of a layer of a semiconductor device, are used in this case. The pattern is arranged in a projection exposure apparatus between an illumination system and a projection lens in the region of the object area of the projection lens and illuminated in the region of the effective object field with illumination radiation provided by the illumination system. The radiation changed by the pattern travels as a projection beam through the projection lens, which images the pattern in the region of the effective image field, which is optically conjugate to the effective object field, onto the substrate to be exposed. The substrate usually carries a layer (photoresist) sensitive to the projection radiation.

When selecting suitable projection exposure apparatuses and methods for a lithography process, different technical and economic criteria are to be taken into account, which are based, among other things, on the typical structure sizes of the structures to be produced within the exposed substrate.

Projection exposure apparatuses with high-NA projection lenses, which typically operate at operating wavelengths in the range of deep ultraviolet radiation (DUV), e.g. at approximately 193 nanometers (nm), are often used for producing relatively fine, critical structures.

By contrast, for the production of medium-critical or non-critical layers with typical structure sizes of significantly more than 150 nm, projection exposure apparatuses that are designed for operating wavelengths of more than 200 nm are traditionally used. In this wavelength range, purely refractive (dioptric) reduction lenses are often used. The optical elements share a common linear optical axis. The object field and image field can be centered with respect to the optical axis (on-axis field). In specific cases, exposures of a full field in stepper mode (step-and-repeat) are thus possible, as a result of which high throughput rates (complete exposures per unit time) are facilitated.

Projection exposure apparatuses for an operating wavelength of 365.5 nm±2 nm (so-called i-line systems) have been in use here for a long time. They use the i-line of mercury vapor lamps, wherein the natural bandwidth thereof is limited to a narrower used bandwidth Δλ, e.g. of about 2 nm, via a filter or in other ways. During the projection, ultraviolet light of a relatively broad wavelength band is usually used in light sources of this type, such that the projection lens brings about a relatively strong correction of chromatic aberrations in order to ensure low-aberration imaging at the desired resolution even with such a broadband projection light.

It has already been suggested to use catadioptric projection lenses for this wavelength range (cf. DE 10 2006 022 958 A1), i.e. projection lenses containing both refractive optical elements with a refractive power, i.e. lens elements, and also reflective elements with a refractive power, i.e. curved mirrors. Typically, at least one concave mirror is contained.

If a catadioptric projection lens is to be constructed without a polarization-selective physical beam splitter and have no pupil obscuration and no beam vignetting, an off-axis field is used in a rotation-symmetric construction of the system, i.e. a configuration in which the effective object field and the effective image field lie outside the optical axis.

The size of an off-axis field is generally limited due to desired geometry and performance. For example, in general a full field (as in the case of a stepper) cannot be realized, and so an exposure is effected in the scan mode. This can involve more technology to achieve a high throughput.

Most conventional projection exposure apparatuses are designed to image a single effective object field into a single effective image field. There are also approaches to use two beam paths at the same time, e.g. to increase throughput.

U.S. Pat. No. 8,634,060 B2 describes a projection exposure apparatus that can expose two masks and two wafers simultaneously. The light from a single light source is alternately transmitted via a fast optical switch through two separate, identical projection systems, each comprising an illumination system and a projection lens.

US 2008/259440 describes a projection exposure apparatus that works with two separate masks and two separate illumination systems, wherein the projection beam paths in the projection lens are merged via a triangular prism.

US 2010/0053738 (corresponding to U.S. Pat. No. 8,705,170 B1) describes projection lenses that use a single mask and branch the projection beam path in the projection lens with the aid of deflection mirrors in such a way that two separate image-side lens parts are formed, which generate two image fields, so that two wafers can be exposed simultaneously. A patent application filed at the same time (and published as US 2010/0053583) discloses corresponding illumination systems, which can simultaneously illuminate two separate illumination fields located at a distance from each other on the same mask. Diffractive optical elements or prisms are provided for splitting the beam coming from the light source. Lens-element arrays of a fly's eye lens are provided for the homogenization of the illumination radiation.

Projection exposure apparatuses with two projection beam paths are, for example, described in patent specification U.S. Pat. No. 8,384,875 using schematic examples. For illuminating the mask, two illumination systems are provided, which can be constructed separately from each other or may be integrated into a common illumination system (FIG. 12 of U.S. Pat. No. 8,384,875). There are also schematic examples of catadioptric projection lenses. Specification data for reworking the systems are not disclosed.

### SUMMARY

The disclosure seeks to provide practically feasible concepts for catadioptric dual-field projection lenses, a projection exposure apparatus equipped therewith, and projection exposure methods which can be carried out therewith.

According to an aspect of the disclosure, a catadioptric projection lens comprising a multiplicity of optical elements, which are arranged along an optical axis between an object plane and an image plane parallel to the object plane, is provided. The projection lens is designed as a dual-field projection lens and is configured to image a first effective object field, arranged outside the optical axis in the object plane, along a first projection beam path into a first effective image field, located outside the optical axis in the image plane, and to simultaneously image a second effective object field, arranged opposite to the first object field with respect to the optical axis outside the optical axis in the object plane, along a second projection beam path into a second effective image field located outside the optical axis in the image plane.

Each of the projection beam paths comprises a first deflection unit for deflecting the radiation coming from the object plane to a concave mirror and a second deflection unit for deflecting the radiation coming from the concave mirror in the direction of the image plane. The projection lens thus has at least two concave mirrors, for example exactly two concave mirrors, namely a single concave mirror per projection beam path.

The optical elements form a first lens part for imaging each of the effective object fields of the object plane into a first real intermediate image, a second lens part for generating a second real intermediate image with the radiation coming from the first lens part, and a third lens part for imaging the second real intermediate image into the image plane. The concave mirror of a projection beam path is arranged in the region of a pupil surface lying between the first and the second intermediate image. The first deflection unit is arranged in optical proximity to the first intermediate image, and the second deflection unit is arranged in optical proximity to the second intermediate image.

This design approach can help allow for the construction of projection lenses that work with two simultaneously usable fields of practically usable size, with a structural mass that is compact overall. In principle, the dimensional design of the deflection units is complicated by boundary conditions. If deflection surfaces can be designed to be relatively large, a vignetting-free deflection of larger fields is relatively easy to implement, but it usually results in a considerable structural size. If the structural size is kept small, the reflective surfaces may become too small for the size of the fields to be projected, increasing the risk of vignetting. The provision of two intermediate images can create conditions for projecting or imaging practically usable field sizes from the object plane into the image plane using relatively small mirror surfaces.

The two projection radiation paths can be used selectively or as an alternative to each other. It is possible to use the two off-axis effective object fields simultaneously. This means that it is possible to expose an area of the substrate having twice the size per unit time compared to a conventional projection lens with only one off-axis object field of the same size. This can help allow higher throughput than conventional off-axis projection lenses.

The optical elements can comprise a multiplicity of lens elements and two concave mirrors. According to a development, a plurality of lens elements are arranged along first portions of the optical axis. The first portions are coaxial relative to one another and perpendicular to the object plane and image plane. The concave mirrors are arranged on opposite sides of the first portions and define second portions of the optical axis, which are oriented transversely to the first portions. The optical axis is thus folded. Overall, the projection lens has rotational symmetry with respect to the folded optical axis. The first portions and the second portions lie in a common plane, referred to here as the axis plane. The optical elements are arranged and formed symmetrically to a plane of symmetry. The plane of symmetry runs perpendicular to the axis plane through the first portions. For each of the concave mirrors, a first deflection unit for deflecting the radiation coming from the object plane to the concave mirror and a second deflection unit for deflecting the radiation coming from the concave mirror in the direction of the image plane are provided. The deflection units are respectively arranged on the side of the plane of symmetry facing the assigned concave mirror.

The concave mirrors can be arranged coaxially relative to one another so that the second portions are oriented perpendicular to the first portions. The projection lens then can have an overall cross-type arrangement of optical elements. The two concave mirrors can lie coaxially opposite with respect to each other on different sides of the plane of symmetry.

It is also possible that the second portions are oriented transversely to the first portions or to the plane of symmetry at an angle deviating from 90°, which may be useful in terms of installation space, for example.

The deflection units can be respectively arranged on the side of the plane of symmetry facing the associated concave mirror. This can help allow two projection beam paths to be used in the projection lens, each leading from an off-axis effective object field to the optically conjugate effective image field. The two off-axis effective object fields can be arranged symmetrically to the plane of symmetry at a distance therefrom on opposite sides, and the same applies to the associated effective image fields.

There are numerous known examples of catadioptric projection lenses in which the optical axis is folded once or more times by 90° in order to integrate one or more concave mirrors into a projection beam path between the object plane and the image plane in such a way that an obscuration-free and vignetting-free image is possible. For folding, plane mirrors (folding mirrors) are typically used which are inclined by 45° relative to an entrance-side portion of the optical axis in order to achieve 90° folding with a single reflection. The conventional plane mirrors are arranged on the side of the optical axis facing away from the concave mirror.

According to a development, this conventional approach is abandoned. Instead, the first deflection unit and the second deflection unit each have a first reflection surface and immediately following a second reflection surface, which are tilted relative to the plane of symmetry by different tilt angles about tilt axes running orthogonally to the first and second portions, wherein the first reflection surface is arranged for deflecting the radiation coming from the object plane to the second reflection surface, and the second reflection surface is arranged for deflecting the radiation coming from the first reflection surface in the direction of the image plane. The deflection units are therefore not designed as 45°-plane mirrors, but as two-stage reflective deflection units, which effect the change in the beam angle of the incident radiation in each case by reflection in two immediately successive stages. In this context, “immediate” means, for example, that there is no other optical element between the first and the second reflective surface.

The deflection units can be arranged in each case on the side of the plane of symmetry facing the associated concave mirror, i.e. on the same side as the associated concave mirror.

The first and second reflection surfaces of a deflection unit can together realize a folding angle of 90°, which is used for the cross-type construction of the projection lens. However, the folding angles may also deviate from 90°.

The tilt angles of the first reflection surfaces and of the second reflection surface can be adapted to each other in such a way that a respective beam that is incident parallel to the entrance-side optical axis on the first reflection surface is deflected by the same angle at the first reflection surface and at the second reflection surface. For example, a deflection by 45° can be provided, resulting in a deflection of 90° in total. The tilt angle is defined here as the angle that the surface normal of a reflection surface encloses with the entrance-side portion of the optical axis. Accordingly, for example, the first tilt angle can be 67.5° and the second tilt angle can be 22.5°. However, in some cases it may be useful to tilt the two reflection surfaces in such a way that they deflect a deflected beam to different degrees.

The reflection surfaces can each be formed on a separate individual mirror, which can be precisely adjusted relative to one another individually, if desired. It is also possible to form two or more reflection surfaces of the deflection units on a common carrier element. For example, a carrier element can be constructed with four triangular prisms. These triangular prisms can be mounted together in the middle of a star-shaped cross section of the deflection unit. Alternatively, all reflection surfaces used for the deflection can be combined and designed as a complex prism with a star-shaped side surface. The complex prism can, for example, include a plurality of individual prisms, which are cemented or contact-bonded to one another.

The first and the second reflection surfaces can be planar, i.e. formed as a plane surface. Within the scope of manufacturing tolerances, deviations from a plane can be in the range of a few percent or a few per thousands of the operating wavelength. However, larger deviations of the surface shape from a planar surface may also be provided specifically, for example, in order to achieve specific influences on the shape of the wavefront.

The intermediate images lie in or near field planes of the projection lens which are optically conjugate to the object plane and image plane. The first deflection unit is arranged in the optical proximity of a first field plane and the second deflection unit in the optical proximity of a second field plane optically conjugate to the first field plane. It is possible due to a near-field arrangement to achieve, among other things, that the reflection surfaces used for deflection can be kept relatively small, so that a compact structural size of a deflection unit is also possible. The first deflection unit and the second deflection unit can be arranged in a region in which a subaperture ratio SAR is less than 0.3 in terms of absolute value. For example, the intermediate image may be arranged between the two individual mirrors of the deflection unit.

The first lens part should not have a magnifying effect if possible, or should not have a strong magnifying effect, so that the size of the first intermediate image does not or does not significantly exceed that of the effective object field. According to a development, the first lens part has a first imaging scale β₁, for which the condition 0.5≤|β₁|≤2.0 applies. If these conditions are met, it is possible to achieve that a practically usable, sufficiently large field size can be transferred or transported completely and thus without vignetting with relatively small mirror surfaces of a deflection unit. If the lower limit is significantly undershot, so that the first lens part has a reducing effect that is too strong, relatively high aperture angles can occur in the region of the deflection unit, so that the deflection cannot be realized with sufficiently small mirror surfaces or can be realized only with very small field sizes. On the other hand, if the upper limit is exceeded, so that the first lens part has a magnifying effect that is too strong, the aperture angles at the deflection unit will decrease, but the latter can have relatively large dimensions in order to be able to completely reflect the relatively large intermediate image. The first lens part can be a 1:1 system; usually the magnification should not exceed a factor of 1.2. The absolute value of the imaging scale β1 of the first lens part can thus be in the range of 1.2 or less. A two-stage deflection in a particularly compact installation space can then be implemented.

According to another formulation, the projection lens can have a reducing imaging scale and the first lens part generates a maximum of half the reduction.

The projection lens can be designed as a scanner system. During scanning, only a part of the object field is imaged by the projection lens at any one time. Therefore, a scanning movement during which adjacent portions of the reticle are successively transferred to the substrate is used to carry out a single exposure step.

So as to transfer the complete pattern of a six inch reticle in a single exposure step with scanning, the effective object field can have a width of 104 millimeters (mm). According to a development, the projection lens is designed with an object field radius OBH of at least 107 mm. The projection lens can be designed such that each of the effective object fields can be 104 mm×56 mm in size and can be located at a distance of 38 mm from the optical axis.

Some embodiments are characterized in that an image-side numerical aperture is less than 0.5, with the numerical aperture optionally being in the range of between 0.2 and 0.4.

The disclosure also relates to a projection exposure method for exposing a radiation-sensitive substrate arranged in the region of an image plane of a projection lens with at least one image of a pattern of a mask arranged in the region of an object plane of the projection lens, in which method a projection lens according to the disclosure is used.

The disclosure also relates to a projection exposure apparatus for exposing a radiation-sensitive substrate arranged in the region of an image plane of a projection lens with at least one image of a pattern of a mask arranged in the region of an object plane of the projection lens, comprising: a primary radiation source for emitting primary radiation; an illumination system for receiving the primary radiation and for generating illumination radiation directed onto the mask; and a projection lens for generating at least one image of the pattern in the region of the image plane of the projection lens, wherein the projection lens is configured according to the disclosure.

The projection lens can be used to scan two adjacent dies simultaneously. A double exposure can also be performed.

The projection exposure apparatus can comprise a central control unit for controlling functions of the projection exposure apparatus, wherein the control device in at least one operating mode is configured to operate the illumination system and the projection lens in such a way that two adjacent dies are scanned simultaneously with the dual-field. In another operating mode, a double exposure can be performed.

Two-stage reflective deflection units of the type described in this application can also be used, e.g. also in single-field catadioptric projection lenses, i.e. having only one effective object field. The disclosure thus also relates to a catadioptric projection lens for imaging a pattern arranged in an object plane of the projection lens into an image plane, parallel to the object plane, of the projection lens, comprising a multiplicity of optical elements, which comprise a plurality of lens elements and a concave mirror and are arranged between the object plane and the image plane along an optical axis to image an effective object field arranged outside the optical axis in the object plane along a projection beam path into an effective image field located outside the optical axis in the image plane, wherein at least one two-stage reflective deflection unit, which has a first reflection surface and immediately following a second reflection surface, is arranged in the projection beam path, wherein the first reflection surface is arranged for deflecting the radiation coming from the object plane to the second reflection surface, and the second reflection surface is arranged for deflecting the radiation coming from the first reflection surface in the direction of the image plane.

For example, it may be the case that in the projection beam path, a first deflection unit for deflecting the radiation coming from the object plane to the concave mirror and a second deflection unit for deflecting the radiation coming from the concave mirror in the direction of the image plane is arranged, wherein the first deflection unit and/or the second deflection unit is formed as a two-stage reflective deflection unit.

It is possible that both the first deflection unit and the second deflection unit are each two-stage reflective deflection units. It is also possible that only one of the deflection units is a two-stage reflective deflection unit and the other deflection unit is a plane mirror, wherein the first deflection unit or the second deflection unit can be a two-stage reflective deflection unit.

### BRIEF DESCRIPTION OF THE DRAWINGS

Further features and aspects of the disclosure are evident from the claims and from the description of exemplary embodiments of the disclosure, which will be explained below with reference to the figures, in which:

FIG. 1 shows a schematic illustration of a projection exposure apparatus according to one exemplary embodiment;

FIG. 2 shows a schematic top view of the object plane of the projection lens with two effective off-axis object fields;

FIG. 3 shows a schematic overview of a first exemplary embodiment for a dual-field illumination system having an integrator rod arrangement;

FIG. 4 shows the integrator rod arrangement from FIG. 3 in detail;

FIGS. 5A-5D show variants of integrator rod arrangements of other exemplary embodiments;

FIG. 6 shows an integrator rod arrangement with two tapered exit integrator rods;

FIG. 7 shows a schematic overview of an exemplary embodiment for a dual-field illumination system with grid elements in a homogenization unit;

FIG. 8 shows the homogenization unit of FIG. 7 in detail;

FIG. 9 shows a schematic meridional lens element sectional view of a projection lens according to a first exemplary embodiment;

FIG. 10 shows an enlarged section of the region of the deflection units in the projection lens of FIG. 9;

FIGS. 11A-11C show three folding situations in comparison;

FIGS. 12A-12B show a variant of single-field scanning;

FIGS. 13A-13B show a variant of dual-field scanning; and

FIG. 14 shows a schematic meridional lens element sectional view of a catadioptric projection lens with two intermediate images, a concave mirror, a two-stage reflective deflection unit, and a single-stage deflection unit.

### DETAILED DESCRIPTION OF EXEMPLARY EMBODIMENTS

In the following description of embodiments, the term “optical axis” denotes a straight line or a sequence of straight line portions through the centers of curvature of the optical elements. The optical axis is folded at folding mirrors (deflection mirrors) or other reflective surfaces. In the examples, the object is a mask (reticle) with the pattern of an integrated circuit; it may also relate to a different pattern, for example of a grating. In the examples, the image is projected onto a wafer provided with a photoresist layer, the wafer acting as a substrate. Other substrates are also possible, for example elements for liquid crystal displays or substrates for optical gratings.

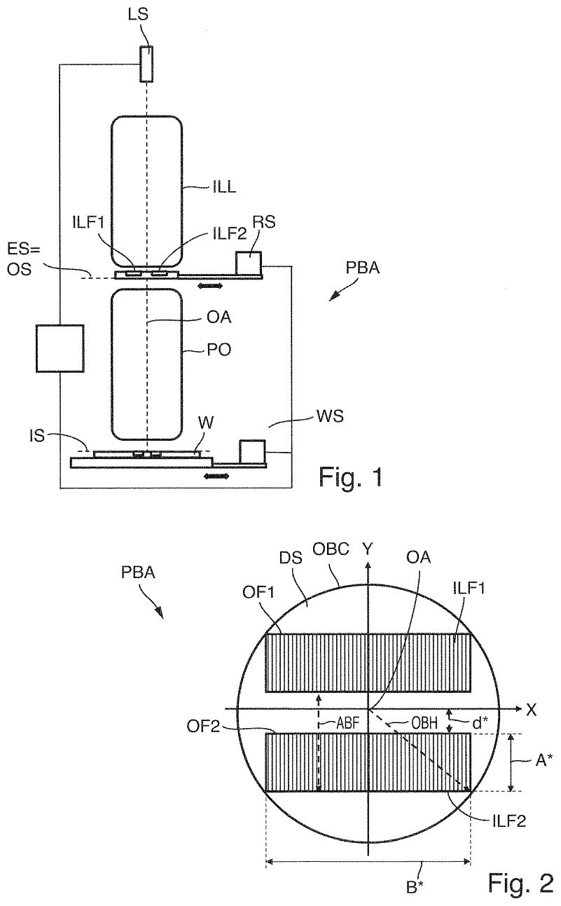

FIG. 1 shows an example of a microlithographic projection exposure apparatus PBA, which is utilizable in the production of semiconductor devices and other finely structured components and which operates with light or electromagnetic radiation from the ultraviolet (UV) range in order to obtain resolutions down to fractions of micrometers. A mercury vapor lamp serves as the primary radiation source or light source LS. The lamp emits a broad spectrum with emission lines of relatively high intensity I in wavelength ranges with centroid wavelengths at 14 pprox . . . 436 nm (visible light, blue, g-line), 14 pprox . . . 405 nm (visible light, violet, h-line), and 14 pprox . . . 365.5 nm (near ultraviolet, UV-A, i-line).

The projection exposure apparatus is an i-line system which uses only the light from the i-line, that is to say UV light around a central operating wavelength of 14 pprox . . . 365.5 nm. The natural full bandwidth of the i-line is restricted to a narrower used bandwidth Δλ, e.g. of about 2 nm, with the aid of a filter or in another way.

In its exit surface ES, an illumination system ILL connected downstream of the light source LS generates from the light from this single primary light source in each case two large, sharply delimited and substantially homogeneously illuminated illumination fields ILF1, ILF2 with beam angles which are adapted to the desired telecentricity of the projection lens PO arranged downstream thereof in the light path.

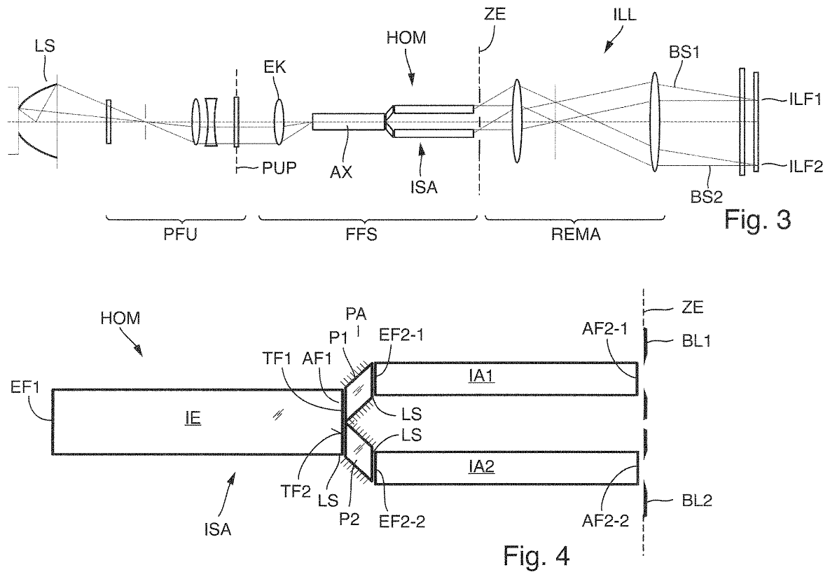

The optical components that receive the light from the light source LS and form from the light illumination radiation which is directed at the reticle M are part of the illumination system ILL of the projection exposure apparatus. The illumination system is a dual-field illumination system. Exemplary embodiments will be explained below in connection with FIGS. 3 to 8.

The illumination system ILL has devices for setting different illumination modes (illumination settings) and can, for example, be switched between conventional on-axis illumination with a different degree of coherence o and off-axis illumination.

Arranged downstream of the illumination system is a device RS for holding and manipulating the mask M (reticle) in such a way that the pattern arranged at the reticle lies in the object plane OS of the projection lens PO, which coincides with the exit plane ES of the illumination system and which is also referred to here as reticle plane OS.

The substrate to be exposed, which is a semiconductor wafer W in the exemplary case, is held by a device WS, which comprises a scanner drive in order to move the wafer synchronously with the reticle M perpendicular to the optical axis OA in a scan direction (y-direction). The device WS, which is also referred to as “wafer stage,” and the device RS, which is also referred to as “reticle stage,” are integral parts of a scanner device which is controlled by a scan control device, which in the embodiment is integrated in the central control device CU of the projection exposure apparatus PBA.

FIG. 2 shows a schematic top view of the object plane OS of the projection lens PO (corresponding to the exit plane ES of the illumination system). As shown in this example, the illumination system ILL illuminates two off-axis illumination fields ILF1, ILF2 with the light from the light source in the exit plane (reticle plane, object plane of the projection lens). These illumination fields are each rectangular, can be sharply or softly delimited, and are substantially homogeneously illuminated. Each of the illumination fields defines an effective object field which is actually used in the projection exposure, so that a first effective object field OF1 and a second effective object field OF2 are located in the reticle plane. The two nominally identically dimensioned rectangular effective object fields lie in the y-direction on opposite sides of the optical axis OA, each with a distance outside the optical axis and have a height A*, measured parallel to the y-direction, and a width B*>A*, measured perpendicular thereto (in the x-direction or cross-scan direction). For example, the aspect ratio AR=B*/A* can be, for example, 2, 2.5, 3, 5, 10 or 15.

In the example case, the effective rectangular fields (i.e. those actually used for imaging) each have a width B*=104 mm and a height A*=56 mm. A distance ABF between corresponding field peripheries in the y-direction (field distance) is twice the distance d* of a field from the optical axis, i.e. 2×38 mm, plus a field height (56 mm), i.e. 132 mm. The circle OBC results from the rectangle with the sides B* (=104 mm) in the x-direction and 2*(A*+d*) (=188 mm) in the y-direction (scan direction).

In the rotationally symmetric system, the circle OBC, which is centered with respect to the optical axis OA, encloses the effective object fields OF1, OF2 and touches their corners, determines the size of the object field circle within which the optical correction corresponds to the specification at all field points. This also applies to all the field points in the effective object fields. The larger this object field is, the more complicated the correction of aberrations becomes. In this case, the size of the circle is parameterized by the object field radius OBH or half the object field diameter OBH, which simultaneously corresponds to the maximum field height of an object field point. The object field height OBH is 16 pprox . . . 107 mm.

The effective image fields IF1, IF2 in the image surface IS, which are optically conjugate to the effective object fields OF1, OF2, have the same shape and the same aspect ratio between height A and width B as the associated effective object fields, but the absolute field size is reduced for reducing projection lenses (with (|β|<1) by the imaging scale β of the projection lens, i.e. A=|β|A* and B=|β|B*.

A distance ABF (field distance) measured in the scan direction (y-direction) between the edges of the effective object fields lying in each case on the same side in the y-direction is selected so that the corresponding distance between corresponding longer edges of the effective image fields IF1, IF2 is exactly the length of a “die” to be exposed. This length is 33 mm in the current standard. In semiconductor and microsystem technology, the term “die” refers to a single non-enclosed piece of a semiconductor wafer, as a single semiconductor chip without a housing or package.

FIG. 3 shows a schematic overview of a first exemplary embodiment for an illumination system ILL. The primary light source LS is a mercury vapor lamp with a collector mirror, which reflects the light collected into an entrance opening of the illumination system. An alternative (not illustrated) uses a laser as the light source, e.g. a frequency-tripled solid-state laser with a wavelength of 17 pprox . . . 355 nm.

The primary light source is followed by a pupil-shaping unit PFU, which is constructed exclusively with refractive optical components and is designed to generate a defined, local (two-dimensional) intensity distribution in a following pupil surface PUP of the illumination system ILL, and which is sometimes also referred to as a secondary light source or as an illumination pupil. Since properties of the illumination radiation can be influenced or shaped by this local intensity distribution, this pupil surface is also referred to as pupil-shaping surface PUP.

The pupil-shaping unit PFU can be variably adjustable such that different local illumination intensity distributions in the circular illumination pupil can be set depending on the control of optical components of the pupil-shaping unit, for example a conventional illumination setting with a circular illumination spot centered around the optical axis AX, dipole illumination or quadrupole illumination.

A refractive field-shaping system FFS is optically connected downstream of the pupil-shaping unit PFU. It contains the optical components that shape the illumination intensity distribution in the exit surface ES of the illumination system from the light from the pupil-shaping surface. The field-shaping system FSF comprises a homogenization unit HOM for the homogenization of the light received from the pupil-shaping unit. The homogenizing unit has a dual function, since the optical components are also designed in a such a way that the illumination light is divided into a first illumination beam BS1 and a second illumination beam BS2, which are incident on the exit plane at mutual distance from each other. The field-shaping system FFS comprises an input-coupling optical unit EK, which collects the light coming from the pupil-shaping surface and couples it into an entrance surface EF1 of an integrator rod arrangement ISA. This is shown enlarged in FIG. 4.

The integrator rod arrangement ISA comprises an entrance integrator rod IE, which has a planar entrance surface EF1, a planar exit surface EF2 parallel thereto, and four planar side surfaces, which form a rectangular cross section. The entrance integrator rod consists of a material which is transparent to the illumination light. The light is mixed within the entrance integrator rod by multiple total internal reflections at the uncoated or optionally coated outer surfaces (side surfaces) of the integrator rod and thus homogenized and exits in at least partially homogenized form at the exit surface AF1. The entrance integrator rod has a continuously rectangular cross section and defines a longitudinal central axis that lies on the optical axis AX of the illumination system.

The integrator rod arrangement further comprises a first exit integrator rod IA1 and a second exit integrator rod IA2, each having an entrance surface EF2-1 and EF2-2, respectively, and an exit surface AF2-1 and AF2-2, respectively. The two exit integrator rods IA1 and IA2 each have a rectangular cross-sectional shape and a cross-sectional area which is substantially half as large as the cross-sectional area of the entrance integrator rod IE.

The exit integrator rods IA1, IA2 are arranged on diametrically opposite sides at a distance from the optical axis AX of the illumination system. The first exit integrator rod IA1 is optically coupled to a first partial surface TF1 of the exit surface of the entrance integrator rod in such a way that light, which exits through the first partial surface TF1, exclusively enters the first exit integrator rod IA1. The same applies to the opposite side, where the light from the partial surface TF2 enters the second exit integrator rod IA2.

Between the entrance integrator rod IE and the two exit integrator rods IA1, IA2, two prisms P1 and P2 of a prism arrangement PA are arranged. The first prism P1 has a rectangular, planar entrance surface, which directly follows the first partial surface TF1 with an intermediate air gap LS and receives the radiation emerging from this partial surface. The planar exit surface has the same size and lies, with an intermediate air gap, directly in front of the entrance surface of the first exit integrator rod IA1. The prism furthermore has two planar side surfaces, which are oriented at an angle of 45° to the entrance and exit surfaces and each have a reflective coating. They can be made reflective, for example, by applying an aluminum layer or a dielectric coating.

The two deflections at mirror surfaces of a prism that have a parallel offset deflect the light emerging from a partial surface TF to a position further away from the optical axis. Each of the prisms thus optically connects one of the exit integrator rods IA1, IA2 to an assigned partial surface TF1, TF1 of the exit surface AF1 of the entrance integrator rod and guides the light from a position close to the axis to a location far away from the axis.

Using this arrangement, the light entering the entrance integrator rod IE is evenly divided substantially in equal parts over the exit surface AF2-1 of the first exit integrator rod and the exit surface AF2-2 of the second exit integrator rod and at the same time mixed both in the entrance integrator rod and in the exit integrator rods by multiple total internal reflections.

Immediately at the exit of the first exit integrator rod IA1 lies an intermediate field plane ZE of the illumination system. An adjustable field stop BL1 is arranged there, which allows the actual usable field size of the first illumination field IF1 to be infinitely adjusted. A corresponding second field stop BL2 is arranged at the exit of the second exit integrator rod.

A following lens REMA, also known as a REMA lens, images the intermediate field plane of the reticle mask system onto the exit plane of the illumination system or the object plane of the following projection lens. There, the first illumination beam generates the first illumination field ILF1 on one side of the optical axis AX, while the second illumination field ILF2 is illuminated on the opposite side at a distance from the optical axis with the aid of the second illumination beam SB2.

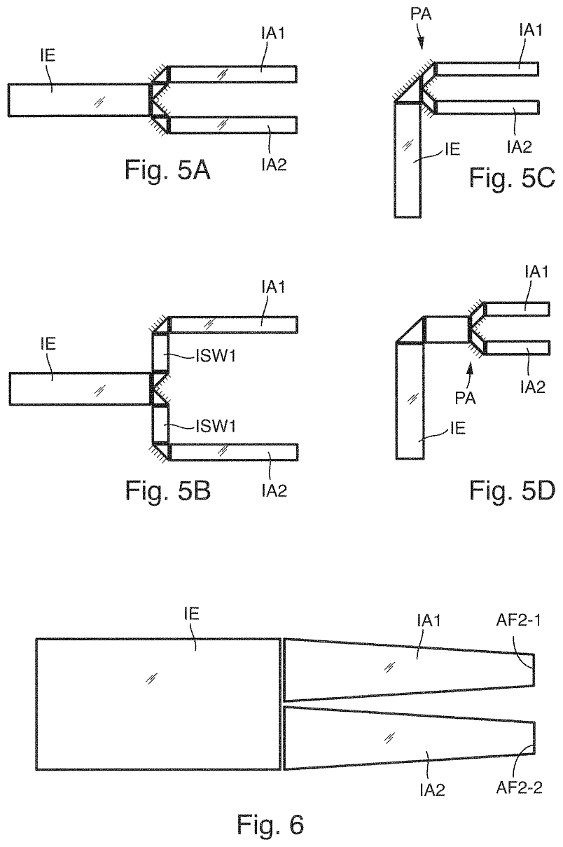

FIGS. 5A to 5C show a few variants of this basic concept. The variant of FIG. 5A differs from the example of FIG. 4 in that the prisms P1 and P2 there are replaced by a pair of triangular prisms. The hypotenuse surfaces of the triangular prisms are reflective in each case, the entrance and exit surfaces are planar and adjoin an upstream or downstream element via an air gap.

FIG. 5B illustrates that a further integrator rod ISW1, ISW2 can also be integrated between the entrance integrator rod IE and the two exit integrator rods IA1, IA2 in each case.

FIG. 5C and FIG. 5D illustrate that the prism arrangement PA, which leads to the division into two illumination beam paths, does not necessarily have to be directly coupled to the exit side of the entrance integrator rod. Rather, further deflection elements and/or integrator rod elements can be interposed.

In the exemplary embodiment of FIG. 6, there are no intermediate prisms and/or other optical elements between the entrance integrator rod IE and the two exit integrator rods IA1 and IA2. In this exemplary embodiment, both exit integrator rods are each designed as a so-called “tapered integrator.” In each of the exit integrator rods IA1, IA2, the size of the rectangular entrance surface EF1, EF2 substantially corresponds to half the area of the exit surface AF1 of the entrance integrator rod IE, with the result that the light emerging in each case from the assigned partial surface is fully coupled into the exit integrator rod. However, while in the previous examples the integrator rods each have a constant cross-sectional shape and cross-sectional size over their lengths, the cross-sectional area of the exit integrators continuously changes in the example of FIG. 6 between the entrance surface and the exit surface such that the two exit surfaces AF2-1 and AF2-2 are arranged diametrically opposite to the optical axis at a distance from the latter. By increasing the angles during the passage through the tapered integrator rods, different illumination may possibly be used at the entrance of the entrance integrator rod and the rod illumination is adapted such that no violation of the conservation of etendue occurs.

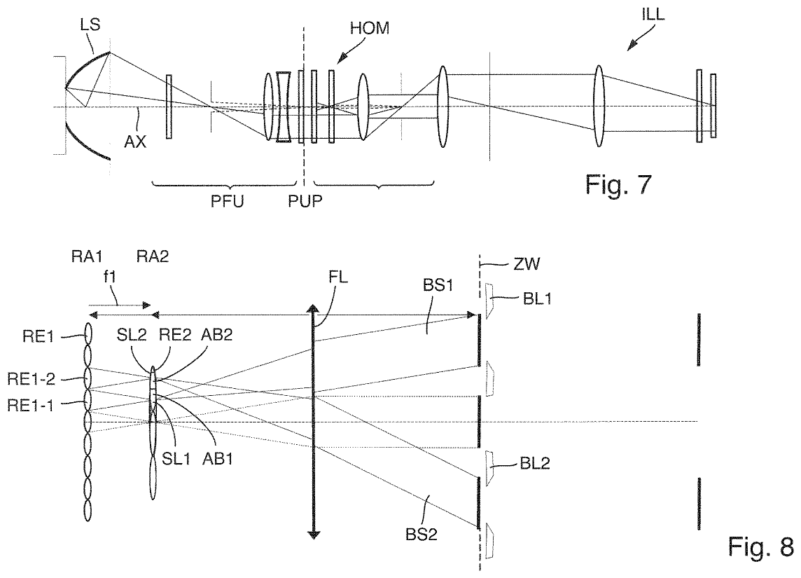

Based on FIG. 7 ff. a different exemplary embodiment of an illumination system ILL will now be described. For reasons of clarity, functional groups having similar or corresponding functions as in the first exemplary embodiment, are designated accordingly. A significant difference from the previous exemplary embodiments lies in the construction and operation of the homogenization unit HOM, which is constructed substantially with the aid of a modified fly's eye lens. Details regarding the construction and function are shown in FIG. 8.

The homogenization unit HOM comprises a first grid arrangement RA1 with a multiplicity of first refractive grid elements RE1, which receive the light of the two-dimensional intensity distribution of the pupil-shaping surface PUP and generate therefrom a grid arrangement of secondary light sources SL1, SL2, etc., which are formed downstream thereof approximately at the distance of the focal length F1 of the first grid elements RE1. In this way, the illumination beam coming from the pupil-shaping surface is broken down into a multiplicity of optical channels, wherein each illuminated first grid element and the associated secondary light source are part of a separate optical channel.

There is a second grid arrangement RA2 with second refractive grid elements RA2, which is arranged optically downstream of the first grid arrangement, for example in the region of the secondary light sources SL1 etc., and serves to receive light from the respective optical channels or the secondary light sources and to contribute to the light coming from different optical channels being at least partially superposed in the region of the exit plane or image plane of the illumination system ILL. This superposition causes homogenization of the light intensity in the exit plane.

The cross-sectional area or aperture of the first grid elements RE1 determines the shape of the illuminated illumination fields and is rectangular in the example case. The first grid elements REI are also referred to as field honeycombs.

The second grid elements RE2 are also referred to as pupil honeycombs and are arranged close to the respective secondary light sources. They image the first grid elements RE1 via a downstream field lens onto an intermediate field plane FE of the illumination system. The intermediate field plane is then imaged into the exit plane of the illumination system, as in the example above.

A special feature of this homogenization unit lies in the fact that each of the first grid elements RE1 generates (as in a conventional fly's eye lens) an optical channel belonging to the secondary light source.

However, each of the second grid elements RE2 is not only assigned to one first grid element, but to two, immediately adjacent first grid elements, e.g. the grid elements RE1-1 and RE1-2. The second grid elements are each formed by a lens element which is divided into two differently shaped portions. A first portion AB1 acts exclusively on the light of an assigned first grid element in its optical channel. A second portion AB2 is formed in a single piece with the first portion, is located exclusively in the adjacent second optical channel, and influences its light propagation accordingly.

In the example case, the first optical channel produced by a grid element R1-1 is influenced by the lower half of the following second grid element or its first portion AB1 such that the light is input into a first illumination beam BS1 via the field lens FL, while the light which is coupled into a second optical channel by the adjacent first grid element R1-2 is influenced by the second portion AB2 of the second grid element such that it is coupled into a second illumination beam BS2, which propagates with respect to the first illumination beam on the opposite side with respect to the optical axis AX.

In order to achieve the strongly differing optical effects at the second grid elements RE2, provision can be made for both the entrance surface and the exit surface to be respectively aspheric in the first portion AB1 and in the second portion AB2. The surface shapes of the first portion and of the second portion do not merge smoothly into each other; rather, a buckling line forms as a separating line between the two portions on the surface of the second grid element.

A feature of this mixing concept is thus that a dense arrangement of several refractive powers, alternating in one spatial direction, with two different surface shapes is produced in the region of the pupil honeycombs (second grid elements RE2). For example, there is a dense arrangement of refractive powers with transitions that are not continuously differentiable. The second grid elements RE2 (pupil honeycombs) can be thought of as lens elements composed of off-axis lens element portions, of which can at least one side be aspheric and the size of each corresponds to that of an associated field honeycomb.

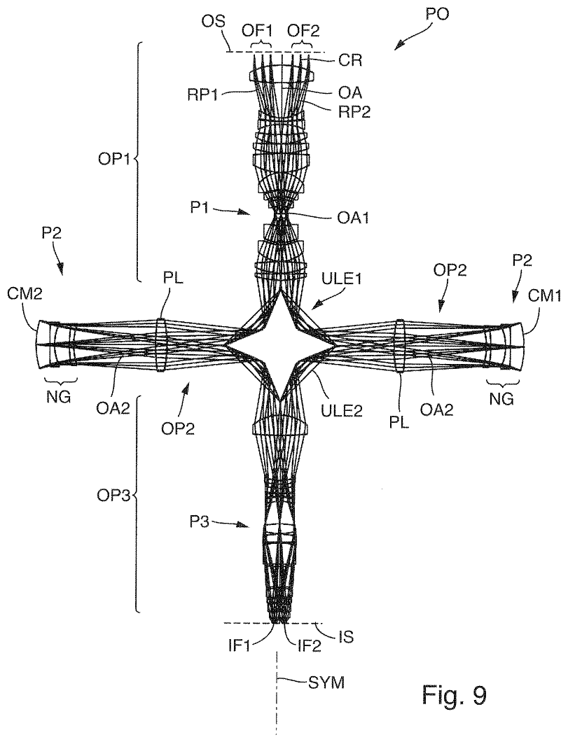

FIG. 9 shows a schematic meridional lens element sectional view of an embodiment of a catadioptric projection lens PO with selected beams for clarifying the imaging beam path of the projection radiation passing through the projection lens during operation. The projection lens is provided as an imaging system with a reducing effect for imaging a pattern of a mask arranged in its object plane OS at a reduced scale, for example the scale 1:4, onto its image plane IS, which is oriented parallel to the object plane.

The projection lens is designed according to one embodiment of the claimed disclosure and has an image-side numerical aperture NA in the range of 0.2<NA<0.4, e.g. NA=0.3.

The projection lens is designed as a double-field projection lens. It is able to image the first effective object field OF1 arranged outside the optical axis OA in the object plane OS along a first projection beam path RP1 into a first effective image field IF1 located outside the optical axis OA in the image plane IS, and simultaneously image a second effective object field OF2, arranged opposite to the first object field with respect to the optical axis outside the optical axis in the object plane, along a second projection beam path RP2 into a second effective image field IF2 located outside the optical axis in the image plane.

The projection lens comprises a multiplicity of optical elements, including numerous lens elements (e.g. between 15 and 25 lens elements) and also exactly two concave mirrors CM1, CM1, with exactly one concave mirror being in each of the projection beam paths.

A majority of the lens elements (more than 50%, such as 60% or more, or 70% or more, or 80% or more), is arranged along first portions OA1 of the optical axis OA, wherein these first portions extend mutually perpendicular coaxially to the object plane OS and image plane IS. The concave mirrors CM1, CM2 are arranged on opposite sides of the first portions OA1 and define second portions OA2 of the optical axis, which together with the first portions define an axis plane (which lies in the drawing plane in FIG. 9). The concave mirrors of the example are arranged coaxially to each other on opposite sides of the first portions, the second portions OA2 of the optical axis are perpendicular to the first portions OA1, producing a cross shape.

The optical elements are arranged and formed mirror-symmetrically to a plane of symmetry SYM, which extends perpendicular to the axis plane (here the drawing plane) through the first portions OA1. For each of the concave mirrors, there is in the assigned projection beam path a first deflection unit ULE1 for deflecting the radiation coming from the object plane OS to the concave mirror and a second deflection unit ULE2 for deflecting the radiation coming from the concave mirror in the direction of the image plane IS. The deflection units ULE1, ULE2 are each arranged on the side of the plane of symmetry SYM facing the assigned concave mirror CM1 and CM2, respectively.

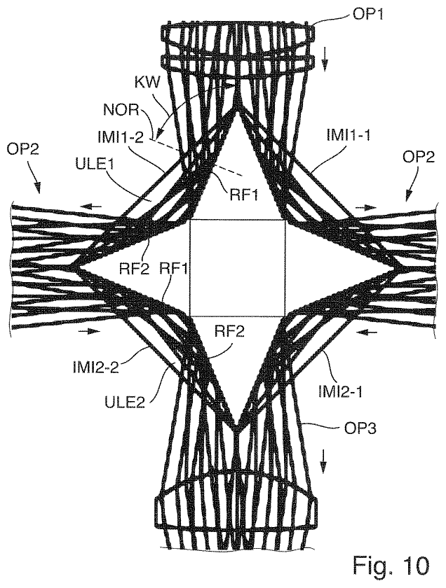

Between the object plane and the image plane, exactly two real intermediate images (generally referred to as IMI) of the assigned effective object field are generated in each of the projection beam paths RP1, RP2, to be precise IMI1-1, IMI2-1 in the first projection beam path and IMI1-2 and IMI2-2 in the second projection beam path (see FIG. 10).

A first lens part OP1, which is constructed exclusively with transparent optical elements and is thus refractive (dioptric) is designed in a manner such that the pattern in each of the illuminated effective object fields is imaged slightly reduced (imaging scale e.g. in the range of 25 pprox . . . 1.85:1 to 25 pprox . . . 1.75:1) into the first intermediate image IMI1-1, IMI1-2 of the respective projection beam path.

A second, catadioptric lens part OP2 images the first intermediate images of the projection beam paths onto the respective second intermediate image IMI2 substantially without changing the size. The second lens part OP2 comprises a separate concave mirror CM1, CM2 and three upstream double-passage lens elements for each of the projection beam paths. In the second lens part, the projection beam paths separate and run along separate optical paths through separate partial lenses before they are recombined to shared lens elements in the region of the second intermediate image IMI2. The second intermediate image IMI2 lies between the two individual mirrors of ULE2, i.e. the projection beam paths are still separated at the second mirrors of ULE2, and only then are they recombined.

A third, refractive lens part OP3 is designed to image the second intermediate images IMI2-1, IMI2-2 at a reduced scale into the image plane IS.

All lens elements of the first lens part OP1 and all lens elements of the third lens part OP3 and thus all lens elements on the first portions OA1 of the optical axis are common to both projection beam paths. The footprints of the projection beam paths on the individual lens element surfaces, i.e. the respective surface areas impinged by radiation, are symmetric to the plane of symmetry SYM. Possible lens heating effects, especially in near-field lens elements, are therefore substantially symmetric to the plane of symmetry, thus simplifying a possible correction.

Located in each of the projection beam paths between the object plane and the first intermediate image, between the first and second intermediate images, and between the second intermediate image and the image plane, are pupil surfaces or pupil planes P1, P2, P3 where the chief ray CR of the optical imaging intersects the optical axis OA. The stop of the system can be disposed in the region of the pupil surface P3 of the third lens part OP3. The pupil surface P2 within the catadioptric second lens part OP2 is located in the immediate vicinity of the respective concave mirror CM.

To support chromatic correction, a negative group NG with at least one diffusing negative lens is arranged in each of the two projection beam paths in the immediate vicinity of the associated concave mirror CM1, CM2 in a region close to the pupil. The “region close to the pupil” here is a region in which the marginal ray height (MRH) of the imaging is greater than the chief ray height (CRH). The marginal ray height in the region of the negative group can be at least twice as great as the chief ray height.

To provide background: while the contributions of lens elements having a positive refractive power and lens elements having a negative refractive power in an optical system to the total refractive power, to the image field curvature and to the chromatic aberrations act in opposite directions, a concave mirror has a positive refractive power exactly like a positive lens element, but has an opposite effect on the image field curvature compared with a positive lens element. In addition, concave mirrors do not introduce chromatic aberrations. Catadioptric system parts with a concave mirror close to the pupil and an adjacent negative lens (Schupmann achromat) is therefore a well-suited mechanism for achromatizing projection lenses. Between the respective deflection unit and the negative group, a double-passage positive lens element PL can be arranged, which can also be omitted in other exemplary embodiments (cf. table 3).

An exceptional technical feature relates to the design of the deflection units ULE1, ULE2. These are not designed as singly reflecting plane mirrors or deflection mirrors. Instead, the first deflection unit ULE1 and the second deflection unit ULE2 each have a substantially planar first reflection surface RF1 and directly following a substantially planar second reflection surface RF2. The reflection surfaces are each tilted relative to the plane of symmetry SYM by different tilt angles about tilt axes, which run orthogonally to the first and second portions. The first reflection surface RF1 is used to deflect the radiation coming from the object plane OS to the second reflection surface RF2, and the second reflection surface is used to deflect the radiation coming from the first reflection surface RF1 in the direction of the image plane.

In each projection beam path, the first reflection surface RF1 is that reflection surface which receives the beams coming from the last lens element of the first lens part OP1 and reflects them in the direction of the immediately following second reflection surface RF2. The latter then reflects the beams within the second lens part OP2 to the associated concave mirror CM. After reflection at the concave mirror and passing twice through the three upstream lens elements, the beams are then incident on the second deflection unit ULE2, whose first reflection surface RF1 deflects the beams to the second reflection surface RF2, which reflects in the direction of the first lens element of the third lens part OP3.

If the tilt angle KW of a reflection surface is defined as the angle that the surface normal NOR of the reflection surface encloses with the entrance-side optical axis, the tilt angle of the first reflection surfaces on the side of the first lens part is 67.5° each. For the immediately following second reflection surfaces in each beam path, the tilt angle is then only 22.5°, i.e. corresponding to the supplementary angle of the first tilt angle, whose sum is 90°. For the second deflection units ULE2, i.e. those which deflect the beams coming from the respective concave mirrors CM in the direction of the third lens part OP3, the same applies, wherein now the second portions OA2 of the optical axis count as the entrance-side optical axis.

With respect to the entrance-side optical axis, a 90° deflection is thus achieved in two immediately successive steps, to be precise once by x degrees and the second time by 90−x°. The two mutually associated reflection surfaces of a deflection unit are located on the same side of the plane of symmetry SYM, specifically on the side in which the associated concave mirror CM is located.

Both reflection surfaces RF1, RF2 of a deflection unit ULE are each located in the optical proximity of the first intermediate image IMI1 of the associated projection beam path, with the result that the footprint of the beam on the reflection surface appears more or less rectangular with rounded corners and is located at a distance from the optical axis, but close thereto. More specifically, the first intermediate image lies between the two reflection surfaces RF1, RF2; in this way both reflection surfaces are close to the intermediate image. At an imaging scale of the first lens part OP1 with at most very small magnification or slight reduction, the size of the intermediate image is not or only slightly larger than the size of the generating effective object field OF, so that mirror surfaces with compact dimensions are sufficient to reflect the entire beam to the downstream optical element without vignetting. This applies for example to the reflection from the first reflection surface RF1 to the second reflection surface RF2, which can also be very compact in size because it still lies in the optical proximity of the first intermediate image, such as in a region in which the subaperture ratio SAR is less than 0.3 in terms of absolute value. SAR can be between 0.2 and 0.3.

For explanatory purposes: the optical proximity or the optical distance of an optical surface to a reference plane (e.g. a field plane or a pupil plane) is described in this application by the so-called subaperture ratio SAR. The subaperture ratio SAR of an optical surface is defined as follows for the purposes of this application:

SAR=sign(CRH)*(MRH/(|CRH|+|MRH|))

where MRH denotes the marginal ray height, CRH denotes the chief ray height, and the signum function sign (x) denotes the sign of x, where according to convention sign (0)=1. The chief ray height is the ray height of the chief ray of a field point of the object field with a maximum field height in terms of absolute value. The ray height should here be understood to be signed. Marginal ray height is the ray height of a ray with a maximum aperture starting from the intersection of the optical axis with the object plane. This field point does not need to contribute to the transfer of the pattern arranged in the object plane—especially in off-axis image fields.

The subaperture ratio is a signed variable that is a measure of the field vicinity or pupil vicinity of a plane in the beam path. By definition, the subaperture ratio is normalized to values between −1 and +1, wherein the subaperture ratio is zero in each field plane and wherein the subaperture ratio jumps from −1 to +1 or vice versa in a pupil plane. A subaperture ratio of 1 in terms of absolute value thus specifies a pupil plane.

Near-field planes thus have subaperture ratios which are close to 0, while near-pupil planes have subaperture ratios close to 1 in terms of absolute value. The subaperture ratio sign indicates the position of the plane in front of or behind a reference plane.

The reflection surfaces can be nominally designed as planar surfaces, i.e. define a mathematical plane aside from manufacturing tolerances. It is also possible to design individual or all reflection surfaces with defined deviations from a plane, with the result that the reflection surfaces can serve as correction surfaces for aberrations such as distortion etc.

In the schematic example of FIG. 9, the reflection surfaces are each manufactured as individual mirrors and accommodated in separate mounts. The example of FIG. 10 shows that in each case two of the deflection mirrors or reflection surfaces can be designed combined as a triangular prism. These triangular prisms can be mounted together in the middle of the star-shaped cross section of the deflection unit. Alternatively, all mirrors used for the deflection can be combined and designed as a complex prism with a star-shaped side surface. The prism can, for example, consist of a plurality of individual prisms, which are cemented or contact-bonded to one another.

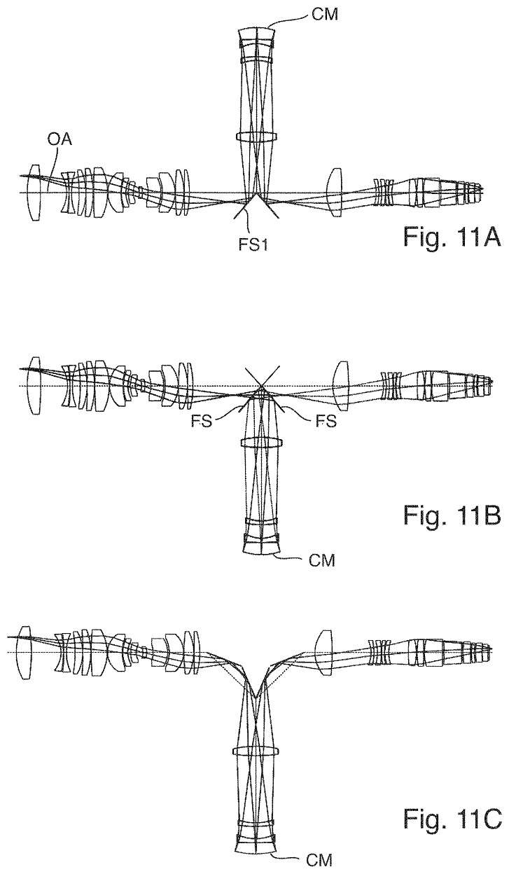

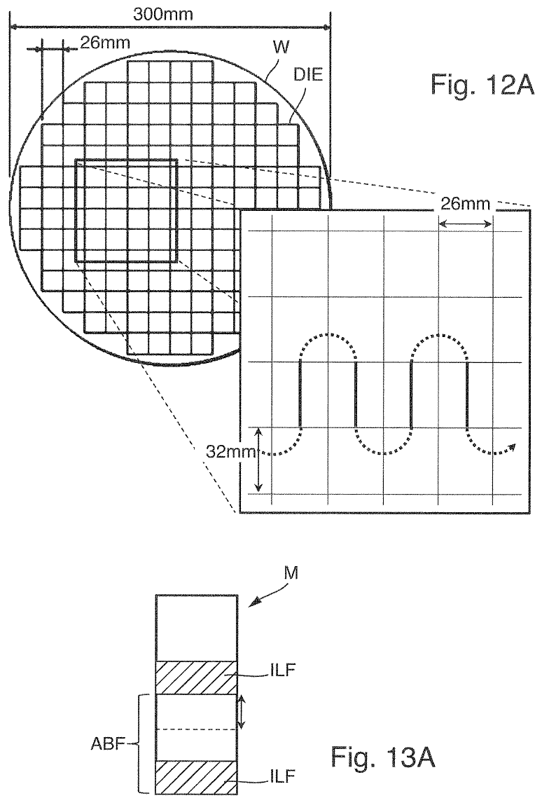

To illustrate features that such double-reflecting deflection units offer in comparison to known technology, FIGS. 11A to 11C show three folding situations for comparison. FIG. 11A shows “classical” folding in a catadioptric projection lens with a single concave mirror CM. The first deflection mirror FS1, which reflects the radiation coming from the object plane OS to the concave mirror CM, lies on the side, of the parts of the optical axis that are perpendicular to the object plane and image plane, which faces away from the concave mirror. The same applies to the second deflection mirror, which deflects the rays coming from the concave mirror into the third lens part.

If two fields were to be used at the same time, the folding mirror of each field would block the respective beam path of the opposite field. It is therefore only possible to image a single field.

In order to allow the (simultaneous) imaging of two fields, the deflection unit should be located on the side of the optical axis facing the associated horizontal arm or concave mirror. FIG. 11B shows an attempt at an implementation with conventional plane mirrors. In the folding variant in FIG. 11B, the folding mirrors FS reflect in each case in the other direction, i.e. the concave mirror is located on the side which is opposite the effective object field. In this case, the folding mirrors are disposed in their own beam path. As a result, there is no functioning system.

A difference between FIGS. 11B and 11C lies in the fact that the rays in FIG. 11C are located at the first deflection unit on the left (on the object side) of the optical axis of the horizontal arm (OA2) and after the reflection at the concave mirror at the second deflection unit on the right (on the image side) of OA2. In FIG. 11B, this is the other way around. As a result, the second deflection unit would have to be to the left of the first deflection mirror (i.e. closer to the object plane) and thus in the beam path object—first deflection mirror.

FIG. 11C shows for comparison the folding with two deflection mirrors per 90° deflection, i.e. with a two-stage reflective deflection unit according to an exemplary embodiment of the present disclosure. It can be seen that a separation of the beam paths leading to the individual concave mirrors can be achieved in this way.

The following text will explain some practical features of dual-field projection lenses. An increase in throughput (exposed components per unit time) can be achieved by the possibility of exposing two off-axis fields simultaneously. This is achieved in the projection lens, among other things, by the fact that two catadioptric partial lenses are contained in the second lens part, that is, two horizontal arms, each containing a concave mirror. The lens parts containing the concave mirrors are each symmetric to the plane of symmetry. The axis of symmetry is an imaginary line that runs through the optical axis OA and runs parallel to the wide sides of the effective image field.

The field distance ABBF of the two effective image fields in the scan direction (y-direction) is ideally such that the sum of the slit width of one field (A*) and the distance between the two fields corresponds exactly to the width of a stepper field (cf. situation in FIG. 2, which shows the object field).

The dual fields can be used either scanning for a double exposure or with the aid of a step-and-scan method.

In the first case, two identical structures would have to be arranged next to each other on the reticle or mask. During scanning, the substrate, such as a wafer, is exposed in quick succession by the first field with the first structure and then by the second field with the second, identical structure. During a normal scan, regions at the far periphery of the wafer are exposed only once. This can be prevented if the scan is started with some overflow. It is conceivable that the second image field is blocked in the overflow region.

In the second case, two different structures can also be arranged next to each other on the reticle, which can be combined to form a structure that is twice as large. The step-and-scan operation would then scan the two fields and then jump to the next dual field in a stepping step.

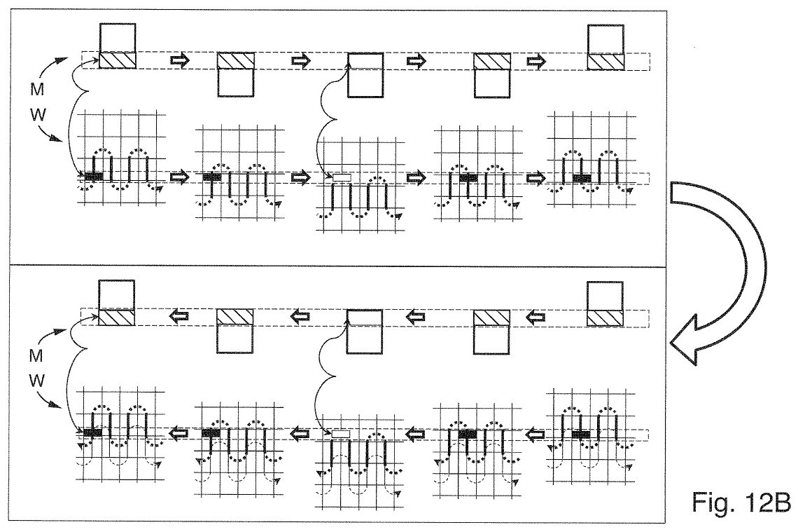

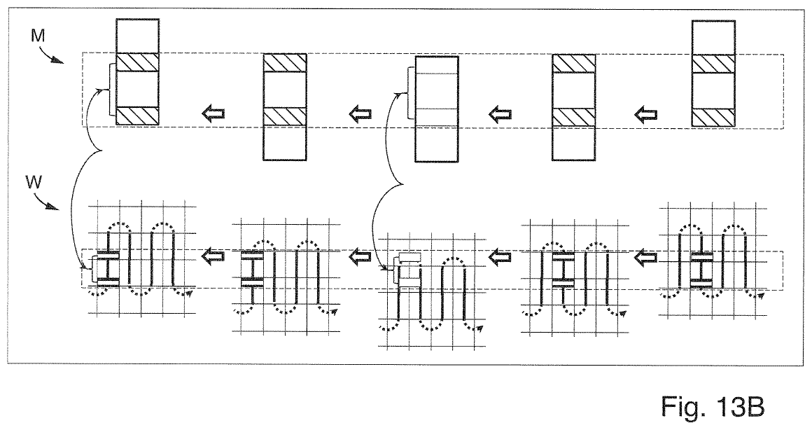

The following figures are used to explain some of the special features of the scanning. FIG. 12A shows a schematic top view of a wafer on which numerous directly adjoining rectangular exposure units DIE (dies) with the current standard dimensions of 26 mm in width and 32 mm in length are provided. The enlarged section in FIG. 12A and FIG. 12B illustrates a typical conventional scanning operation. The wafer meanders under the projection lens or the image field or scanning slit used for the exposure. There are two different states. In a scan phase, which is shown in FIGS. 12A, 12B as a solid line, the substrate and the mask or the wafer and the reticle move at a uniform and adapted speed (depending on the imaging scale of the projection lens) and a die is exposed. After each scanning operation, a change of direction occurs, which is marked in FIGS. 12A, 12B by dashed lines. This stops the movement of the reticle while the wafer is moving. The movement comprises a deceleration phase, a movement perpendicular to the scan direction, and then an acceleration in the opposite direction. There is no exposure during the change of direction, so this phase is not productive. FIGS. 12A, 12B schematically illustrate the chronological sequence of the two phases.

For comparison, FIG. 13B shows different phases of a scanning operation with the aid of a projection exposure apparatus with dual field and two rigidly coupled scanning slits with a geometry, which is shown schematically in FIG. 13A. It is immediately apparent that the scan phases now extend over the length of two immediately successive dies, so that two dies can be exposed simultaneously during a scan phase. In comparison with the scan phases, the unproductive change of direction takes place only half as often as in the classical scanning operation in the sense that, in the classical operation, a change of direction takes place after the scanning of a die, while in the case of a dual field, a change of direction takes place only after the scanning of two dies.

In order to enable this type of scanning, the two scanning slits or the effective image fields in the exemplary embodiment are arranged according to FIG. 13A.

The scanning operation with the double exposure corresponds to the scanning operation for a single field in terms of reticle and wafer movement. One die is exposed in each case for the first time, and an adjacent die is exposed for the second time. The difference to the scanning operation for a single field is that at the top and bottom periphery of the wafer, the illumination of one of the two fields is switched off so that it is not exposed beyond the periphery of the wafer.

The previous examples illustrate that the two-stage folding at the two deflection units of each projection beam path allows the use of dual fields. There are other potential uses and features relatively to single folding. One example is the avoidance of the so-called “image flip” with a catadioptric projection lens with a single concave mirror and two intermediate images.

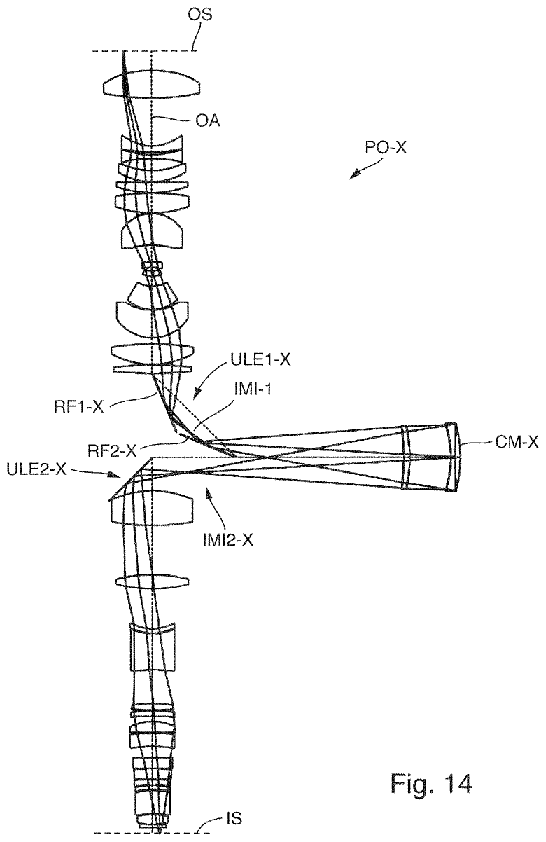

Such projection lenses offer features, for example in terms of correcting chromatic aberrations, but can exhibit an “image flip” is generated during the imaging. This means that features which are described in a right-handed coordinate system on the reticle are described with a left-handed coordinate system in the image plane. This unfavorable property results from the fact that the handedness changes between the object plane and the image plane at each intermediate image and at each reflection. If the sum of the number of intermediate images and the number of reflections is an odd number, the result is an image flip. If this sum is an even number, an image flip is avoided. This will be explained below using a comparison between a classical projection lens according to FIG. 11A and a projection lens PO-X according to FIG. 14.

FIG. 14 shows a lens element sectional view through a catadioptric projection lens PO-X, which images an effective object field in the object plane, which is located outside the optical axis, into an off-axis effective image field located in an image plane. Two real intermediate images IMI1-X and IMI2-X are produced between the object plane and the image plane. The projection lens has a single concave mirror with an upstream negative group to support the correction of the chromatic aberrations. A first deflection unit ULE1-X directs the radiation coming from the object plane in the direction of the concave mirror. A second deflection unit ULE2-X directs the radiation reflected by the concave mirror in the direction of the image plane. While the second deflection unit is formed by a simple plane mirror and causes a single reflection, the first deflection unit ULE-X is designed as a two-stage reflective deflection unit. The latter has a first reflection surface RF1-X, which deflects the radiation coming from the object in the direction of a second, immediately following reflection surface RF2-X. The latter then reflects the radiation in the direction of the concave mirror. The two reflection surfaces can then be arranged on separate individual mirrors; they can be formed on a common carrier element in order to fix their mutual orientations. Between the object plane and the image plane there are two intermediate images and a total of four reflections, so the sum of intermediate images and reflections is an even number. Thus, the image flip existing in conventional systems of this type (see FIG. 11A) is avoided. Alternatively, the first deflection unit could be single-stage and the second deflection unit could be two-stage. As with the classical system, the deflection mirrors are each arranged in the optical proximity of the associated intermediate images, i.e. in a near-field region.

The use of two-stage reflective deflection units of the kind described in this application is not limited to the exemplary embodiments. It is also possible to use such deflection units in a projection lens which produces only one intermediate image between the object plane and the image plane or generates direct imaging without an intermediate image. It may be the case that a two-stage reflective deflection unit is arranged in the projection beam path behind an upstream plane mirror and/or in front of a downstream deflection mirror.

The following tables summarize the specifications of the two exemplary embodiments. Tables 1 and 1A apply to the exemplary embodiment of FIG. 9 with NA=0.3, tables 2 and 2A apply to an exemplary embodiment that is not shown in an image with NA=0.28 and without a positive lens element in the double-passage beam path between the deflection units and the concave mirror.

The tables summarize the specification of the respective design in tabular form. The “SURF” column indicates the number of a refractive surface or surface with a different characteristic, the “RADIUS” column indicates the radius r of the surface (in mm), the “THICKNESS” column indicates the distance d of the surface from the following surface (in mm), and the “MATERIAL” column indicates the material of the optical components. Columns “INDEX1,” INDEX2” and “INDEX3” indicate the refractive index of the material at wavelengths 365.5 nm (INDEX1), 364.5 nm (INDEX2) and 366.5 nm (INDEX3). The “SEMIDIAM” column shows the usable free radii or the half free optical diameters of the lens elements (in mm) or optical elements. The radius r=0 (in the “RADIUS” column) corresponds to a planar surface. Some optical surfaces are aspheric. Tables with the suffix “A” indicate the corresponding asphere data, wherein the aspheric surfaces are calculated according to the following rule:

$$p ( h ) = \frac{ϱ {h}^{2}}{1 + \sqrt{1 - ( 1 + K ) {( ϱ h )}^{2}}} + {C}_{1} {h}^{4} + {C}_{2} {h}^{6} + {C}_{3} {h}^{8} + ⋯$$

The reciprocal value

$$\frac{1}{r} = ϱ$$

of the radius indicates the surface curvature, and h indicates the distance of a surface point from the optical axis (i.e. the ray height). Thus, p(h) indicates the sag height, i.e. the distance of the surface point from the surface vertex in the z-direction (direction of the optical axis). The coefficients K, C1, C2 . . . are shown in the tables with the suffix “A.”

TABLE 1

| SURF | RADIUS | THICKNESS | MATERIAL | INDEX1 | INDEX2 | INDEX3 | SEMID. | TILT | TILT |
|---|---|---|---|---|---|---|---|---|---|
| 0 (0BJ) | planar | 35.506913 | | 1 | 1 | 1 | 0.0 | | |
| 1 | 313.669085 | 60.694812 | SiO2 | 1.474188175 | 1.47447703 | 1.4747711 | 110.0 | | |
| 2 | −801.556319 | 120.055216 | | 1 | 1 | 1 | 105.8 | | |
| 3 | −107.586369 | 10.262231 | SiO2 | 1.474188175 | 1.47447703 | 1.4747711 | 76.1 | | |
| 4 | −396.017812 | 1.463990 | | 1 | 1 | 1 | 78.4 | | |
| 5 | −607.605491 | 10.121204 | SiO2 | 1.474188175 | 1.47447703 | 1.4747711 | 78.5 | | |
| 6 | 280.688349 | 35.518156 | | 1 | 1 | 1 | 80.3 | | |
| 7 | −462.835188 | 30.596703 | SiO2 | 1.474188175 | 1.47447703 | 1.4747711 | 84.0 | | |
| 8 | −194.369860 | 1.149336 | | 1 | 1 | 1 | 88.9 | | |
| 9 | −1162.886135 | 31.741706 | SiO2 | 1.474188175 | 1.47447703 | 1.4747711 | 92.6 | | |
| 10 | −278.287998 | 1.434923 | | 1 | 1 | 1 | 95.5 | | |
| 11 | 1420.872642 | 64.194980 | SiO2 | 1.474188175 | 1.47447703 | 1.4747711 | 96.8 | | |
| 12 | −194.50 [symbol] 027 | 0.984694 | | 1 | 1 | 1 | 97.5 | | |
| 13 | 94.060920 | 60.024719 | SiO2 | 1.474188175 | 1.47447703 | 1.4747711 | 78.3 | | |
| 14 | 192.679744 | 1.559950 | | 1 | 1 | 1 | 62.0 | | |
| 15 | 131.356932 | 20.032900 | SiO2 | 1.474188175 | 1.47447703 | 1.4747711 | 58.4 | | |
| 16 | 94.034713 | 11.814077 | | 1 | 1 | 1 | 46.5 | | |
| 17 | 125.870327 | 22.130617 | SiO2 | 1.474188175 | 1.47447703 | 1.4747711 | 42.1 | | |
| 18 | 61.964170 | 27.496928 | | 1 | 1 | 1 | 29.6 | | |
| 19 | −64.969877 | 15.098409 | SiO2 | 1.474188175 | 1.47447703 | 1.4747711 | 20.5 | | |
| 20 | −100.479877 | 26.837998 | | 1 | 1 | 1 | 23.9 | | |
| 23 | −95.104123 | 57.961946 | SiO2 | 1.474188175 | 1.47447703 | 1.4747711 | 35.1 | | |
| 22 | −117.375749 | 6.745188 | | 1 | 1 | 1 | 58.1 | | |
| 23 | −135.145839 | 57.688418 | SiO2 | 1.474188175 | 1.47447703 | 1.4747711 | 61.3 | | |
| 24 | −109.341889 | 1.171987 | | 1 | 1 | 1 | 78.8 | | |
| 25 | 751.633206 | 39.157305 | SiO2 | 1.474188175 | 1.47447703 | 1.4747711 | 87.8 | | |
| 26 | −207.194655 | 2.358230 | | 1 | 1 | 1 | 89.4 | | |
| 27 | 12076.748826 | 22.217332 | SiO2 | 1.474188175 | 1.47447703 | 1.4747711 | 88.2 | | |
| 28 | −314.824440 | 30.695817 | | 1 | 1 | 1 | 88.1 | | |
| 29 | planar | 275.202116 | mirror | 1 | 1 | 1 | 145.4 | −67.5 | 67.5 |
| 30 | planar | 198.815360 | mirror | 1 | 1 | 1 | 143.6 | −22.5 | 22.5 |
| 31 | 419.811910 | 36.209117 | SiO2 | 1.474188175 | 1.47447703 | 1.4747711 | 90.8 | | |
| 32 | −671.770102 | 283.160703 | | 1 | 1 | 1 | 90.6 | | |
| 33 | −219.406879 | 15.517185 | SiO2 | 1.474188175 | 1.47447703 | 1.4747711 | 70.8 | | |
| 34 | −366.537484 | 51.362316 | | 1 | 1 | 1 | 72.1 | | |
| 35 | −165.724966 | 16.376894 | SiO2 | 1.474188175 | 1.47447703 | 1.4747711 | 72.1 | | |
| 36 | −2614.277511 | 47.674101 | | 1 | 1 | 1 | 77.0 | | |
| 37 | −296.119320 | 47.674101 | mirror | 1 | 1 | 1 | 84.7 | | |
| 38 | 2614.277511 | 16.376894 | SiO2 | 1.474188175 | 1.47447703 | 1.4747711 | 74.0 | | |
| 39 | 165.725966 | 51.362316 | | 1 | 1 | 1 | 69.5 | | |
| 40 | 366.537484 | 15.517185 | SiO2 | 1.474188175 | 1.47447703 | 1.4747711 | 69.5 | | |
| 41 | 219.406879 | 283.160703 | | 1 | 1 | 1 | 68.2 | | |
| 42 | 671.770102 | 39.209117 | SiO2 | 1.474188175 | 1.47447703 | 1.4747711 | 88.8 | | |
| 43 | −419.811910 | 198.815360 | | 1 | 1 | 1 | 89.0 | | |
| 44 | planar | 275.202116 | mirror | 1 | 1 | 1 | 142.6 | | |
| 45 | planar | 45.307528 | mirror | 1 | 1 | 1 | 145.2 | 22.5 | −22.5 |
| 46 | 137.863448 | 69.500589 | SiO2 | 1.474188175 | 1.47447703 | 1.4747711 | 94.3 | 67.5 | −67.5 |
| 47 | −926.888792 | 156.815279 | | 1 | 1 | 1 | 90.1 | | |
| 48 | −130.164386 | 11.807231 | SiO2 | 1.474188175 | 1.47447703 | 1.4747711 | 52.1 | | |
| 49 | −246.384840 | 14.058199 | | 1 | 1 | 1 | 52.1 | | |
| 50 | −191.014898 | 16.136166 | SiO2 | 1.474188175 | 1.47447703 | 1.4747711 | 50.9 | | |
| 51 | −307.839194 | 1.951201 | | 1 | 1 | 1 | 51.4 | | |
| 52 | 684.693576 | 10.178590 | SiO2 | 1.474188175 | 1.47447703 | 1.4747711 | 51.0 | | |
| 53 | 247.582201 | 1.806825 | | 1 | 1 | 1 | 50.3 | | |
| 54 | 146.261249 | 15.541772 | SiO2 | 1.474188175 | 1.47447703 | 1.4747711 | 50.4 | | |
| 55 | 160.475891 | 73.186277 | | 1 | 1 | 1 | 49.0 | | |
| 56 | planar | 5.154755 | | 1 | 1 | 1 | 49.4 | | |
| (STOP) | | | | | | | | | |
| 57 | 413.071260 | 32.292190 | SiO2 | 1.474188175 | 1.47447703 | 1.4747711 | 51.9 | | |
| 58 | −210.070759 | 3.275760 | | 1 | 1 | 1 | 55.3 | | |
| 59 | 343.765147 | 27.284950 | SiO2 | 1.474188175 | 1.47447703 | 1.4747711 | 56.9 | | |
| 60 | −863.571059 | 2.179246 | | 1 | 1 | 1 | 57.2 | | |
| 61 | 203.377100 | 73.290044 | SiO2 | 1.474188175 | 1.47447703 | 1.4747711 | 57.0 | | |
| 62 | 2660.834310 | 7.191681 | | 1 | 1 | 1 | 50.4 | | |
| 63 | −559.997454 | 70.864313 | SiO2 | 1.474188175 | 1.47447703 | 1.4747711 | 49.8 | | |
| 64 | 1168.97043 [symbol] | 5.276921 | | 1 | 1 | 1 | 45.2 | | |
| 65 | 318.682638 | 30.155097 | SiO2 | 1.474188175 | 1.47447703 | 1.4747711 | 44.9 | | |
| 66 | 8466.525734 | 4.393047 | | 1 | 1 | 1 | 42.9 | | |
| 67 | 234.459718 | 13.609307 | SiO2 | 1.474188175 | 1.47447703 | 1.4747711 | 42.0 | | |
| 68 | 347.975968 | 3.573041 | | 1 | 1 | 1 | 40.5 | | |
| 69 | 173.342050 | 26.558614 | SiO2 | 1.474188175 | 1.47447703 | 1.4747711 | 39.7 | | |
| 70 | 514.184870 | 1.164063 | | 1 | 1 | 1 | 35.9 | | |
| 71 | 191.459647 | 22.140309 | SiO2 | 1.474188175 | 1.47447703 | 1.4747711 | 35.3 | | |
| 72 | 889.725826 | 1.632009 | | 1 | 1 | 1 | 31.4 | | |
| 73 | planar | 5.570294 | SiO2 | 1.474188175 | 1.47447703 | 1.4747711 | 31.1 | | |
| 74 | planar | 12.080020 | | 1 | 1 | 1 | 30.1 | | |
| 75 | planar | 0.000000 | | 1 | 1 | 1 | 0.0 | | |
| (IMG) | | | | | | | | | |

[symbol]

indicates data missing or illegible when filed

TABLE 1A
ASPHERIC CONSTANTS

| SURF | 1 | 3 | 6 | 27 | 31 | 36 | 38 |
|---|---|---|---|---|---|---|---|
| K | 0 | 0 | 0 | 0 | 0 | 0 | 0 |
| C1 | 7.258868E−08 | 2.011577E−07 | 2.636351E−07 | −2.574222E−08 | 1.355011E−09 | −4.728914E−09 | 4.728914E−09 |
| C2 | −5.430882E−12 | −2.059146E−11 | −3.252204E−11 | 1.424412E−12 | 5.941808E−13 | −1.372861E−13 | 1.372861E−13 |
| C3 | 3.619145E−16 | 1.822025E−15 | 2.293197E−15 | 1.304966E−16 | −3.597974E−17 | 1.769076E−17 | −1.769076E−17 |
| C4 | −1.578232E−20 | −7.313131E−21 | −1.255006E−19 | 2.145075E−20 | 1.900153E−21 | 3.267795E−21 | −3.267795E−21 |
| C5 | 5.134497E−25 | −1.162491E−23 | 5.661107E−24 | 2.041821E−24 | −2.847826E−25 | −6.532412E−25 | 6.532412E−25 |
| C6 | −7.407896E−30 | 1.040102E−27 | −1.798991E−28 | −8.339538E−29 | 2.050550E−29 | 2.863773E−29 | −2.863773E−29 |
| C7 | 0 | 0 | 0 | 0 | 0 | 0 | 0 |
| C8 | 0 | 0 | 0 | 0 | 0 | 0 | 0 |
| SURF | 43 | 46 | 48 | 57 | 60 | 64 | |
| K | 0 | 0 | 0 | 0 | 0 | 0 | |
| C1 | −1.355011E−09 | −3.140756E−08 | −7.730092E−08 | −2.290987E−09 | 2.294900E−09 | 5.997172E−08 | |
| C2 | −5.941808E−13 | −1.203411E−12 | −7.180831E−12 | −5.404557E−12 | −3.127903E−12 | 2.871090E−11 | |
| C3 | 3.597974E−17 | 3.765773E−17 | 3.021547E−15 | −1.072780E−15 | −9.887066E−16 | 3.926675E−16 | |
| C4 | −1.900153E−21 | −1.131056E−20 | −1.703028E−18 | 8.128417E−19 | 2.805846E−19 | 3.477523E−19 | |
| C5 | 2.847826E−25 | 1.036560E−24 | 5.257098E−22 | −1.975107E−22 | −4.541180E−23 | −5.147175E−22 | |
| C6 | −2.050550E−29 | −5.506043E−29 | −6.121958E−26 | 1.543922E−26 | 2.704394E−27 | 1.933726E−25 | |
| C7 | 0 | 0 | 0 | 0 | 0 | 0 | |
| C8 | 0 | 0 | 0 | 0 | 0 | 0 | |

TABLE 3

| | | | | | | | | HOA1 [symbol] |
|---|---|---|---|---|---|---|---|---|
| SURF | RADIUS | THICKNESS | MATERIAL | INDEX1 | INDEX2 | INDEX3 | SEMID. | TILT |
| 0 (OBJ) | planar | 43.890445 | | 1 | 1 | 1 | 0.0 | |
| 1 | 317.336786 | 64.705247 | SILUV | 1.474188175 | 1.47447703 | 1.4747711 | 112.0 | |
| 2 | −561.198473 | 111.946272 | | 1 | 1 | 1 | 107.7 | |
| 3 | −84.127688 | 13.445906 | SILUV | 1.474188175 | 1.47447703 | 1.4747711 | 70.1 | |
| 4 | −325.043319 | 6.013108 | | 1 | 1 | 1 | 70.0 | |
| 5 | −204.768360 | 10.666035 | SILUV | 1.474188175 | 1.47447703 | 1.4747711 | 69.9 | |
| 6 | 3962.792918 | 26.118127 | | 1 | 1 | 1 | 71.5 | |
| 7 | −175.926444 | 26.320606 | SILUV | 1.474188175 | 1.47447703 | 1.4747711 | 71.9 | |
| 8 | −147.473400 | 0.996140 | | 1 | 1 | 1 | 78.1 | |
| 9 | −3910.921139 | 24.413188 | SILUV | 1.474188175 | 1.47447703 | 1.4747711 | 82.5 | |
| 10 | −251.313470 | 1.033922 | | 1 | 1 | 1 | [symbol] | |
| 11 | 507.858397 | 46.019262 | SILUV | 1.474188175 | 1.47447703 | 1.4747711 | 84.7 | |
| 12 | −251.876631 | 1.111421 | | 1 | 1 | 1 | 84.0 | |
| 13 | 83.562130 | 73.686537 | SILUV | 1.474188175 | 1.47447703 | 1.4747711 | 71.4 | |
| 14 | 196.054018 | 38.923443 | | 1 | 1 | 1 | 49.0 | |
| 15 | 193.743320 | 12.900681 | SILUV | 1.474188175 | 1.47447703 | 1.4747711 | 23.6 | |
| 16 | 52.041515 | 8.467974 | | 1 | 1 | 1 | 16.9 | |
| 17 | −55.929273 | 11.794515 | SILUV | 1.474188175 | 1.47447703 | 1.4747711 | 17.2 | |
| 18 | −66.852705 | 23.916929 | | 1 | 1 | 1 | 22.7 | |
| 19 | −62.710866 | 54.329347 | SILUV | 1.474188175 | 1.47447703 | 1.4747711 | 34.1 | |
| 20 | −83.137995 | 1.092863 | | 1 | 1 | 1 | 58.3 | |
| 21 | −112.325147 | 64.741097 | SILUV | 1.474188175 | 1.47447703 | 1.4747711 | 61.4 | |
| 22 | −99.058218 | 14.114156 | | 1 | 1 | 1 | 82.0 | |
| 23 | 585.175867 | 47.785588 | SILUV | 1.474188175 | 1.47447703 | 1.4747711 | 95.4 | |
| 24 | −194.175480 | 1.116844 | | 1 | 1 | 1 | 96.5 | |
| 25 | 517.329281 | 19.528447 | SILUV | 1.474188175 | 1.47447703 | 1.4747711 | 91.5 | |
| 26 | −919.103095 | 1.011638 | | 1 | 1 | 1 | 90.4 | |
| 27 | planar | 276.741691 | mirror | 1 | 1 | 1 | 147.4 | −67.5 |
| 28 | planar | 390.934377 | mirror | 1 | 1 | 1 | 142.0 | −67.5 |
| 29 | −512.591931 | 13.766398 | SILUV | 1.474188175 | 1.47447703 | 1.4747711 | 74.6 | |
| 30 | −328.702071 | 95.302534 | | 1 | 1 | 1 | 75.4 | |
| 31 | −250.445951 | 10.423331 | SILUV | 1.474188175 | 1.47447703 | 1.4747711 | 75.9 | |
| 32 | 1672.621399 | 11.678478 | | 1 | 1 | 1 | 78.4 | |
| 33 | −310.916878 | 11.678478 | mirror | 1 | 1 | 1 | 78.4 | |
| 34 | −1672.621399 | 10.423331 | SILUV | 1.474188175 | 1.47447703 | 1.4747711 | 78.4 | |
| 35 | 250.445951 | 95.302534 | | 1 | 1 | 1 | 75.9 | |
| 36 | 328.702071 | 13.766398 | SILUV | 1.474188175 | 1.47447703 | 1.4747711 | 75.2 | |
| 37 | 512.591931 | 390.934377 | | 1 | 1 | 1 | 74.4 | |
| 38 | planar | 276.741691 | mirror | 1 | 1 | 1 | 143.3 | 67.5 |
| 39 | planar | −3.093996 | mirror | 1 | 1 | 1 | 148.5 | 67.5 |
| 40 | 207.660139 | 80.619429 | SILUV | 1.474188175 | 1.47447703 | 1.4747711 | 94.3 | |

[symbol]

indicates data missing or illegible when filed

TABLE 3A
ASPHERIC CONSTANTS

| SURF | 1 | 3 | 6 | 17 | 19 | 25 | 32 |
|---|---|---|---|---|---|---|---|
| K | 0 | 0 | 0 | 0 | 0 | 0 | 0 |
| C1 | 8.343405E−08 | 5.197994E−07 | 4.357373E−07 | −1.240495E−06 | 2.351387E−07 | −4.070498E−08 | −6.699475E−09 |
| C2 | −1.857642E−12 | −3.604842E−11 | −4.317549E−11 | −5.211367E−09 | 4.179078E−10 | −2.318935E−13 | −2.187419E−13 |
| C3 | −2.394648E−18 | 6.475431E−15 | 3.471888E−15 | 4.301288E−11 | −4.172236E−13 | −3.254201E−16 | 9.752181E−17 |
| C4 | 5.875239E−21 | −4.030577E−20 | −1.523606E−19 | −1.954661E−13 | 4.340189E−16 | 7.980012E−20 | −9.830275E−21 |
| C5 | −1.842466E−25 | 1.195428E−23 | −9.260882E−25 | 4.495646E−16 | −5.605434E−19 | −1.220270E−23 | 3.362668E−25 |
| C6 | −7.993131E−30 | 5.758602E−27 | 8.725334E−27 | −9.598243E−19 | 4.681548E−22 | 8.645204E−28 | 2.715949E−28 |
| C7 | −5.447442E−34 | −1.831438E−30 | −2.400936E−30 | 3.084553E−21 | −1.527855E−25 | −1.393533E−32 | 1.206633E−31 |
| C8 | 5.957414E−38 | 2.882257E−34 | 1.949680E−34 | −4.755141E−24 | 3.779847E−30 | −9.471846E−37 | −1.146114E−35 |
| SURF | 34 | 40 | 44 | 49 | 52 | 60 | 67 |
| K | 0 | 0 | 0 | 0 | 0 | 0 | 0 |
| C1 | 6.699475E−09 | −3.065834E−08 | 2.360624E−08 | 2.448140E−07 | 2.367421E−07 | 2.719354E−07 | 3.815887E−07 |
| C2 | 2.187419E−13 | 2.654377E−13 | −1.492506E−12 | −3.839945E−11 | −2.349121E−11 | 6.515650E−11 | −2.605052E−10 |
| C3 | −9.752181E−17 | −6.061174E−18 | 2.165630E−14 | 3.607894E−14 | 2.226650E−14 | 1.905337E−14 | 5.005764E−13 |
| C4 | 9.830275E−21 | 4.757296E−21 | −2.558652E−17 | −1.090641E−17 | −3.064922E−18 | −5.192838E−17 | −9.098221E−16 |
| C5 | −3.362668E−25 | −4.681420E−24 | 1.723006E−20 | −2.832473E−21 | −6.695116E−21 | 5.486918E−20 | 8.249081E−19 |
| C6 | 2.715949E−28 | 1.087152E−27 | −6.544300E−24 | 2.340678E−24 | 4.670988E−24 | −3.514661E−23 | −2.134755E−22 |
| C7 | −2.677731E−33 | −1.057149E−31 | 1.302283E−27 | −3.866787E−28 | −1.258728E−27 | 1.339572E−26 | −1.533643E−25 |
| C8 | −3.939833E−36 | 3.773424E−36 | −1.054878E−31 | 1.277414E−33 | 1.255664E−31 | −2.194746E−30 | 7.918414E−29 |

What is claimed is:

1. A catadioptric projection, lens comprising:
a multiplicity of optical elements comprising lens elements and concave mirrors along an optical axis between an object plane of the catadioptric projection lens and an image plane of the catadioptric projection lens, wherein:
the image plane is parallel to the object plane;
the projection lens is a dual-field projection lens configured to image:
i) a first effective object field outside the optical axis in the object plane along a first projection beam path into an effective image field outside the optical axis in the image plane; and
ii) at the same time as i), a second effective object field outside the optical axis in the object plane along a second projection beam path into a second effective image field outside the optical axis in the image plane, the second effective object field being opposite the first object field with respect to the optical axis;
each of the first and second projection beam paths comprises:
i) a first deflection unit configured to deflect radiation coming from the object plane to a concave mirror; and
ii) a second deflection unit configured to deflect radiation coming from the concave mirror in the direction of the image plane;
the multiplicity of optical elements defines:
i) a first lens part configured to image each of the first and second effective object fields into a corresponding first real intermediate image;
ii) for each of the first and second projection beam paths, a corresponding second lens part configured to generate a corresponding second real intermediate image with the radiation coming from the first lens part; and
iii) a third lens part configured to image the second real intermediate image into the image plane; and
for each of the first and second projection beam paths, a concave mirror is disposed in a region of a pupil surface between the first and second intermediate images;
the first deflection unit is in an optical proximity of the first intermediate image; and
the second deflection unit is in an optical proximity of the second intermediate image.

2. The projection lens of claim 1, wherein:
the lenses are disposed along first portions of the optical axis extending mutually perpendicular coaxially to the object plane and the image plane;
the concave mirrors are on opposite sides of the first portions and define second portions of the optical axis;
the first and second portions define an axis plane;
the optical elements are disposed symmetrically relative to a plane of symmetry extending perpendicular to the axis plane through the first portions; and
each of the first and second deflection units is on a side of the plane of symmetry facing the corresponding concave mirror.

3. The projection lens of claim 2, wherein the concave mirrors are arranged coaxially to one another on opposite sides of the first portions and define second portions which are oriented orthogonally to the first portions.

4. The projection lens of claim 2, wherein:
each of the first second deflection units comprises a first reflection surface immediately following a second reflection surface;
the first and second reflection surfaces are tilted relative to the plane of symmetry by different tilt angles about tilt axes running orthogonally to the first and second portions;
the first reflection surface is configured to deflect the radiation coming from the object plane to the second reflection surface; and
the second reflection surface is configured to deflect the radiation coming from the first reflection surface in the direction of the image plane.

5. The projection lens of claim 4, wherein the tilt angles of the first and second reflection surfaces are configured so that a respective beam that is incident parallel to the entrance-side optical axis on the first reflection surface is deflected by the same angle at the first reflection surface and at the second reflection surface.

6. The projection lens of claim 1, wherein the first and second deflection units are in a region in which an absolute value of a subaperture ratio is less than 0.3.

7. The projection lens of claim 1, wherein:
the first lens part has a first imaging scale β₁; and
0.5≤|β₁|≤2.0 and/or the projection lens has a reducing imaging scale with the first lens part configured to generate a maximum of half the reduction.

8. The projection lens of claim 1, wherein the projection lens has an image-side numerical aperture of less than 0.5.

9. The projection lens of claim 1, wherein, in the projection beam path between the effective object field in the object plane and the effective image field in the image plane, a sum of reflections and intermediate images is an even number for each of the first and second projection beam paths.

10. The projection lens of claim 1, wherein:
the lenses are disposed along first portions of the optical axis extending mutually perpendicular coaxially to the object plane and the image plane;
the concave mirrors are on opposite sides of the first portions and define second portions of the optical axis;
the first and second portions define an axis plane;
the optical elements are disposed symmetrically relative to a plane of symmetry extending perpendicular to the axis plane through the first portions;
each of the first and second deflection units is on a side of the plane of symmetry facing the corresponding concave mirror;
the first lens part has a first imaging scale β₁; and
0.5≤|β₁|≤2.0 and/or the projection lens has a reducing imaging scale with the first lens part configured to generate a maximum of half the reduction.

11. An apparatus, comprising:
the projection lens of claim 1; and
an illumination system configured to simultaneously illuminate the first and second effective object fields,
wherein the apparatus is a microlithography projection exposure apparatus.

12. The apparatus of claim 11, wherein the illumination system comprises:
a refractive pupil-shaping unit configured to receive light from a primary light source and to generate a two-dimensional intensity distribution in a pupil-shaping surface of the illumination system; and
a refractive field-shaping system optically downstream of the pupil-shaping unit, the refractive field-shaping unit comprising a homogenization unit configured to homogenize the light received from the pupil-shaping unit and to divide the illumination light into the first illumination beam and the second illumination beam.

13. The apparatus of claim 12, wherein:
the homogenization unit comprises an integrator rod arrangement;
the integrator rod arrangement comprises:
an entrance integrator rod comprising an entrance surface and an exit surface;
a first exit integrator rod optically coupled to a first partial surface of the exit surface; and
a second exit integrator rod optically coupled to a second partial surface of the exit surface;
an exit surface of the first exit integrator rod is assigned to the first illumination field; and
an exit surface of the second exit integrator rod is assigned to the second illumination field.

14. The apparatus of claim 12, wherein:
the homogenization unit comprises a first grid arrangement and a second grid arrangement;
the first grid arrangement comprises first refractive grid elements configured to receive light of the two-dimensional intensity distribution and to generate a grid arrangement of secondary light sources;
the second grid arrangement comprises second refractive grid elements configured to receive light from the secondary light sources and to at least partially superpose light from the secondary light sources in the exit plane; and
each first grid element is configured to produce an optical channel;
each of the second grid elements is assigned to two adjacent first grid elements;
each of the second grid elements comprises a lens element comprising a first portion in a first optical channel and a second portion a second optical channel; and
the first and second portions have different surface shapes.

15. A method of using a microlithography projection exposure apparatus comprising an illumination system and a projection lens, the method comprising:
using the illumination system to simultaneously illuminate first and second effective object fields of the projection lens; and
using the projection lens to project the first and second effective object fields into corresponding first and second effective image fields,
wherein the projection lens comprises a projection lens according to claim 1.

16. A catadioptric projection lens, comprising:
a multiplicity of optical elements comprising a plurality of lens elements and a concave mirror between the object plane and the image plane along an optical axis to image an effective object field outside the optical axis in the object plane along a projection beam path into an effective image field outside the optical axis in the image plane, wherein:
an at least two-stage deflection unit is in the projection beam path;
the at least two-stage deflection unit comprises a first reflection surface and immediately following a second reflection surface;
the first reflection surface is configured to deflect radiation coming from the object plane to the second reflection surface;
the second reflection surface is configured to deflect radiation coming from the first reflection surface in the direction of the image plane so that the first reflection surface and the second reflection surface define a folding angle of 90°.

17. The projection lens of claim 16, wherein:
a first deflection unit is configured to deflect the radiation coming from the object plane to the concave mirror; and
a second deflection unit is configured to deflect the radiation coming from the concave mirror in the direction of the image plane; and
the first deflection unit is a two-stage reflective deflection unit and/or the second deflection unit is a two-stage reflective deflection unit.

18. The projection lens of claim 17, wherein the first deflection unit is a two-stage reflective deflection unit, and the second deflection unit is a plane mirror.

19. An apparatus, comprising:
the projection lens of claim 16; and
an illumination system configured to the effective object field,
wherein the apparatus is a microlithography projection exposure apparatus.

20. A method of using a microlithography projection exposure apparatus comprising an illumination system and a projection lens, the method comprising:
using the illumination system to illuminate an effective object fields of the projection lens; and
using the projection lens to project the effective object field into an effective image field,
wherein the projection lens comprises a projection lens according to claim 16.
